(19) United States
(12) Patent Application Publication
(10) Pub. No.: US 2010/0033263 A1
(43) Pub. Date: Feb. 11, 2010

(54) FLAT TRANSMISSION WIRE AND FABRICATING METHODS THEREOF

(75) Inventors: Woon Phil BAIK, Yongin-si (KR); Kwan Sik JANG, Incheon (KR)

Correspondence Address: Workman Nydegger;1000 Eagle Gate Tower, 60 East South Temple, Salt Lake City, UT, 84111, US

(73) Assignee: NANO CHEM TECH, Yongin-si (KR)

(21) Appl. No.: 12/535,802

(22) Filed: Aug. 5, 2009

(30) Foreign Application Priority Data
Aug. 8, 2008 (KR) 10-2008-0077963
Feb. 19, 2009 (KR) 10-2009-0014085
Mar. 27, 2009 (KR) 10-2009-0026407

(51) Int. Cl. H01P 5/12; H05K 3/10

(52) U.S. Cl. 333/100; 29/846

(57) ABSTRACT

A flat transmission wire is provided which includes a first insulating or dielectric film, a transmission layer formed on at least one surface of the first insulating or dielectric film so as to transmit electrical signals therethrough, a second insulating or dielectric film formed on one surface of the transmission layer, and a functional layer formed on one surface of the second insulating or dielectric film. Further provided are methods for fabricating flat transmission wires which enable the formation of uniform and fine transmission line patterns, and are environmental friendly, as compared to deposition-based methods.

### CROSS-REFERENCE TO RELATED APPLICATION

This application claims priority to and the benefit of Korean Patent Applications No. 10-2008-0077963, filed on Aug. 8, 2008, No, 10-2009-0014085, filed on Feb. 19, 2009, and No. 10-2009-0026407, filed on Mar. 27, 2009, the entire content of which is incorporated herein by reference.

### BACKGROUND OF THE INVENTION

1. Field of the Invention

The present invention relates to a flat transmission wire and methods for fabricating the same. More specifically, the present invention relates to a flat transmission wire that is light in weight, simple to install, which has a good appearance and can effectively minimize crosstalk and transmission loss in the wire, as well as methods for fabricating flat transmission wires in a simple and environmentally friendly manner at low cost.

2. Description of the Related Art

A transmission wire is a signal transmission path having an electrical length. Conventional round cable wires are inconvenient to install, have poor appearance because round lines tend to be exposed to the outside, have a heavy unit weight, and have a negative influence on the environment due to carbon dioxide being emitted during fabrication processes. Flat transmission wires can be installed within materials used for indoor and outdoor flooring of buildings to simplify the configuration of interconnections between devices, which gradually become more complex. Flat transmission wires have received considerable attention as replacements for power cables and transmission cables.

U.S. Pat. No. 6,774,741 discloses a method of fabricating a non-uniform flat transmission wire in which transmission lines are formed on the upper and lower surfaces of an insulating layer by deposition and then covered with overlying and underlying insulating layers. However, the non-uniform flat transmission wire suffers from a noise loss resulting from non-uniform and discontinuous intervals between the transmission lines under actual conditions of use. This noise loss shortens the transmission distance of the transmission lines and increases the loss of transmission signal, which limit the signal transmission of the flat transmission wire.

According to conventional methods for fabricating flat linear transmission wires, transmission lines are attached or deposited one by one. This attachment or deposition makes it difficult to form a fine pattern of the transmission lines. Accordingly, various shapes and kinds of transmission wires are not obtained. Further, the conventional methods involve complicated steps, incur high costs, and cause environmental problems during deposition.

In a conventional flat transmission wire, a general insulator film is deposited on transmission lines or an aluminum foil/fully deposited film is used for electromagnetic shielding. In the event that only the insulator film is used in the transmission wire, crosstalk or loss of transmission signal may be caused because no electromagnetic shielding effect is expected. Meanwhile, the use of the aluminum foil/fully deposited film as electromagnetic shielding causes difficulty in controlling the impedance of the transmission wire, despite the excellent electromagnetic shielding effect, and is disadvantageous in terms of thickness and price.

### BRIEF SUMMARY OF THE INVENTION

In view of the above problems, an object of the present invention is to provide a flat transmission wire that is simple to install, has good appearance and can effectively minimize crosstalk and transmission loss.

Another object of the present invention is to provide methods for fabricating flat transmission wires in a simple and environmentally friendly manner at low cost.

According to an aspect of the present invention, there is provided a flat transmission wire which includes a first insulating or dielectric film, a transmission layer formed on at least one surface of the first insulating or dielectric film to transmit electrical signals therethrough, a second insulating or dielectric film formed on one surface of the transmission layer, and a functional layer formed on one surface of the second insulating or dielectric film.

The transmission layer may include a plurality of linear transmission lines.

The functional layer may have at least one function selected from antistatic properties, electromagnetic shielding, electromagnetic absorption, dielectric properties, conductivity and colorability.

The functional layer may contain a material selected from conductive polymers, carbon nanotubes (CNTs), organic silver complexes, indium tin oxide (ITO), and mixtures thereof.

The conductive polymers may include polyaniline, polypyrrole, polythiophene, poly(3,4-ethylenethiophene), derivatives thereof, copolymers thereof, π-conjugated conductive polymers soluble in water, π-conjugated conductive polymers soluble in organic solvents, and mixtures thereof.

The organic silver complexes may include a reaction product of a silver-containing compound and an ammonium compound of Formula 1:

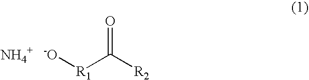

wherein R₁ is C₁-C₅ alkyl, and R₂ is hydrogen, hydroxyl, C₁-C₅ alkoxy, C₁-C₅ alkylammonium, C₁-C₆ alkoxyammonium or a substituted or unsubstituted primary, secondary or tertiary amine.

The functional layer may be formed in a mesh pattern.

The flat transmission wire may further include a tape layer formed on one surface of another second insulating or dielectric film opposite to the functional layer and including an adhesive layer and a release film attached to one surface of the adhesive layer.

According to another aspect of the present invention, there is provided a method for fabricating a flat transmission wire, the method including: forming a transmission layer by a pressure-sensitive adhering a conductive material to at least one surface of an insulating or dielectric film; and patterning by converting the transmission layer to form a transmission line pattern.

The method may further include forming a multiple transmission layer by adhering the flat transmission wire fabricated by the forming a transmission layer to the pattering to each of both surfaces of an insulating or dielectric film.

The method may further include forming a multiple transmission layer by adhering an insulating or dielectric film having a conductive material adhered to one surface thereof to one surface of the transmission layer before the patterning step.

The converting may be performed by slitting, pressing or lamination.

The conductive material is adhered by a pressure-sensitive adhesive which has an adhesive strength of 0.2 to 200 gf/25 mm and is selected from the group consisting of acrylic resins, urethane resins, epoxy resins, urethane-acrylic resins, silicone resins, amide resins and mixtures thereof.

The method may further include forming a functional layer by adhering an insulating or dielectric film having a functional layer, which has at least one function selected from antistatic properties, electromagnetic shielding, electromagnetic absorption, dielectric properties, conductivity and colorability, formed on one surface thereof to one surface of the transmission layer, after the patterning step.

According to another aspect of the present invention, there is provided a method for fabricating a flat transmission wire, the method including: forming a transmission layer by adhering a conductive material to one surface of a first insulating or dielectric film; pressure-sensitive adhering a second insulating or dielectric film to one surface of the transmission layer; pattering by converting the first insulating or dielectric film to the transmission layer to form a transmission line pattern; forming a functional layer by adhering a third insulating or dielectric film having a functional layer formed on one surface thereof to one surface of the patterned transmission layer; and removing the second insulating or dielectric film.

The method may further include forming a insulating layer by adhering a fourth insulating or dielectric film to the surface of the transmission layer from which the second insulating or dielectric film has been removed.

The method may further include forming a tape layer by coating an adhesive on one surface of the fourth insulating or dielectric film to form an adhesive layer and attaching a release film to one surface of the adhesive layer.

According to yet another aspect of the present invention, there is provided a method for fabricating a flat transmission wire, the method including: forming a transmission layer by adhering a conductive material to at least one surface of a first insulating or dielectric film; forming a transmission line by cutting the first insulating or dielectric film and the transmission layer in a direction perpendicular to the upper surface of the flat transmission wire and parallel to the lengthwise direction of the flat transmission wire to form a plurality of transmission lines; arranging the transmission lines so as to be spaced apart from each other at regular intervals; and laminating a second insulating or dielectric film on at least one surface of each of the transmission lines.

The method may further include forming a functional layer by coating a conductive coating solution on one surface of the second insulating or dielectric film.

The method may further include cutting between the two adjacent transmission lines of the flat transmission wire including the plurality (n) of transmission lines, in a direction perpendicular to the upper surface of the flat transmission wire and parallel to the lengthwise direction of the flat transmission wire to fabricate multiple flat transmission wires, each including one or more (m) transmission lines fewer than n.

The lamination may be performed by thermal curing or melting at a temperature of 30 to 250° C. to adhere the second insulating or dielectric film to the transmission lines.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a cross-sectional view of a flat transmission wire according to a first embodiment of the present invention;

FIG. 2 is a flow chart illustrating a method for fabricating a flat transmission wire according to a first embodiment of the present invention;

FIGS. 3A-3C are cross-sectional views sequentially illustrating the steps of the method of FIG. 2;

FIG. 4 is a flow chart illustrating a method for fabricating a flat transmission wire according to a second embodiment of the present invention;

FIG. 5A is a cross-sectional view illustrating the step of forming a plurality of transmission layers in the method of FIG. 4;

FIG. 5B is a cross-sectional view illustrating the patterning step in the method of FIG. 4;

FIG. 6 is a flow chart illustrating a method for fabricating a flat transmission wire according to a third embodiment of the present invention;

FIG. 7 is a cross-sectional view illustrating the step of forming a plurality of transmission layers in the method of FIG. 6;

FIG. 8 is a flow chart illustrating a method for fabricating a flat transmission wire according to a fourth embodiment of the present invention;

FIGS. 9A-9G are cross-sectional views sequentially illustrating the steps of the method of FIG. 8;

FIG. 10 is a flow chart illustrating a method for fabricating a flat transmission wire according to a fifth embodiment of the present invention;

FIG. 11A is a perspective view illustrating the step of forming transmission layers in the method of FIG. 10; and

FIGS. 11B-11G are cross-sectional views sequentially illustrating the other steps of the method of FIG. 10.

### DETAILED DESCRIPTION OF THE INVENTION

Exemplary embodiments of the present invention will now be described in detail with reference to the accompanying drawings in such a manner that a person skilled in the art can easily carry out the present invention from the teaching of the detailed description.

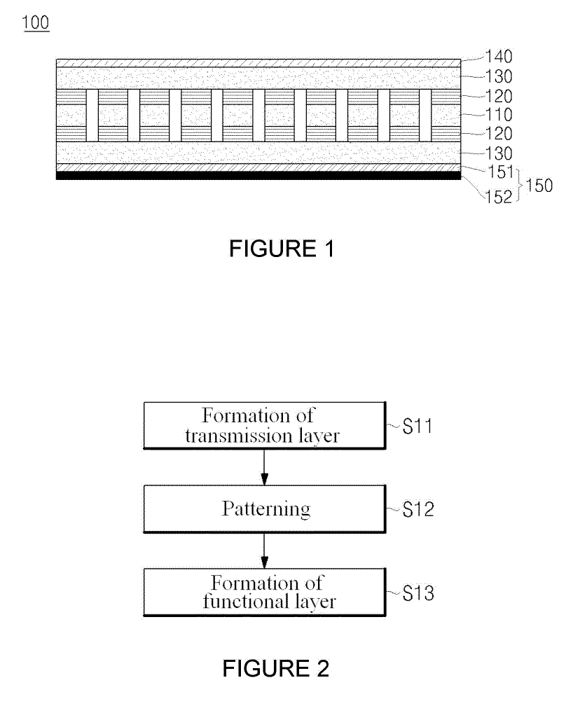

FIG. 1 is a cross-sectional view of a flat transmission wire 100 according to an embodiment of the present invention. Referring to FIG. 1, the flat transmission wire 100 may include a first insulating or dielectric film 110, transmission layers 120, second insulating or dielectric films 130, and a functional layer 140. The flat transmission wire 100 may further include a tape layer 150.

The first insulating or dielectric film 110 serves to insulate the transmission layers 120. The first insulating or dielectric film 110 may be made of a polymeric material selected from thermoplastic resins, copolymers of thermoplastic resins, and blends of thermoplastic resins. Specific examples of polymeric materials suitable for the first insulating or dielectric film 110 include polyester, polyamide, polystyrene, polyimide, polyolefin resins such as polyethylene and polypropylene, polyvinylidene fluoride, polyvinylene chloride, acrylic-butadiene-styrene copolymers, polycarbonate, polymethylmethacrylate, copolymers thereof, and blends thereof. These polymeric materials may be used alone or as a mixture thereof. The first insulating or dielectric film 110 may have a monolayer or bilayer structure. The first insulating or dielectric film 110 may have a thickness in the range of 0.01 to 5 mm. A first insulating or dielectric film 110 thinner than 0.01 mm is insufficient for insulation between the transmission layers 120. A first insulating or dielectric film 110 thicker than 5 mm makes the flat transmission wire 100 too thick, resulting in poor appearance and workability.

The transmission layers 120 serve to transmit electrical signals therethrough. The transmission layers 120 are formed by adhering a conductive material on both surfaces of the first insulating or dielectric film 110. A transmission layer 120 may be formed on one surface of the first insulating or dielectric film 110. The conductive material may be adhered to the first insulating or dielectric film 110 using a pressure-sensitive adhesive. The conductive material may be selected from metals, polysilicon, ceramics, carbon fibers, conductive inks, conductive pastes, and mixtures thereof. Examples of suitable metals include, but are not limited to, aluminum, copper, nickel, gold and silver. These metals may be used alone or as a mixture thereof.

Each of the second insulating or dielectric films 130 is formed on one surface of the transmission layer 120. The second insulating or dielectric films 130 may be made of a polymeric material selected from thermoplastic resins, copolymers of thermoplastic resins, and blends of thermoplastic resins. Specific examples of polymeric materials suitable for the second insulating or dielectric films 130 include polyester, polyamide, polystyrene, polyimide, polyolefin resins such as polyethylene and polypropylene, polyvinylidene fluoride, polyvinylene chloride, acrylic-butadiene-styrene copolymers, polycarbonate, polymethylmethacrylate, copolymers thereof, and blends thereof. These polymeric materials may be used alone or as a mixture thereof. Each of the third insulating or dielectric films 130 may have a monolayer or bilayer structure. The second insulating or dielectric films 130 may be made of the same material as the first insulating or dielectric film 110.

The functional layer 140 is formed on one surface of one of the second insulating or dielectric films 130. The functional layer 140 may have at least one function selected from antistatic properties, electromagnetic shielding, electromagnetic absorption, dielectric properties, conductivity and colorability. The functional layer 140 may contain a material selected from conductive polymers, carbon nanotubes, organic silver complexes, indium tin oxide (ITO), and mixtures thereof. The functional layer 140 may further contain a printable coating composition. The conductive polymers may include polyaniline, polypyrrole, polythiophene, poly(3,4-ethylenethiophene), derivatives thereof, copolymers thereof, π-conjugated conductive polymers soluble in water, π-conjugated conductive polymers soluble in organic solvents, and mixtures thereof. The carbon nanotubes refer to tubular molecules in which a sheet of graphene made of carbon hexagonal rings, each of which consists of six carbon atoms, connected to one another is rolled up. The carbon nanotubes may have a diameter of a few to a few tens of nanometers. The carbon nanotubes may have a single-wall or multi-wall structure. Preferably, the carbon nanotubes have a diameter between 1 and 100 nm and a length between 1 and 500 μm. The carbon nanotubes below the diameter and length ranges defined above are disadvantageous in terms of production cost. Meanwhile, the carbon nanotubes above the diameter and length ranges defined above are disadvantageous in terms of dispersibility and transparency. Any organic silver complex known in the art can be used without limitation. Preferably, the organic silver complexes may include a reaction product of a silver-containing compound and an ammonium compound of Formula 1:

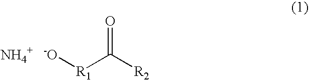

wherein R₁ is C₁-C₅ alkyl, and R₂ is hydrogen, hydroxyl, C₁-C₅ alkoxy, C₁-C₅ alkylammonium, C₁-C₆ alkoxyammonium or a substituted or unsubstituted primary, secondary or tertiary amine.

The ammonium compound of Formula 1 and the silver-containing compound may react in a molar ratio of 2:1 to 5:1. The reaction conditions may be suitably determined by a person skilled in the art. The ammonium compound of Formula 1 may be selected from the group consisting of ammonium carbonate, ammonium carbamate, ammonium bicarbonate, ethylammonium ethylcarbamate, and mixtures thereof. The silver-containing compound may be selected from the group consisting of silver oxide, silver cyanide, silver cyanate, silver carbonate, silver nitrate, silver nitrite, silver phosphate, silver perchlorate, and mixtures thereof. The printable coating composition serves to improve the colorability of the transmission wire. Any printable coating composition known in the art can be used without limitation.

The functional layer 140 may be formed in a mesh pattern so as not to completely cover one of the second insulating or dielectric films 130. The mesh pattern enables the control of impedance and a variety of functions of the flat transmission wire 100 to minimize crosstalk and loss of transmission signal. The mesh pattern may be in the form of a net or lattice. The inner spaces of the net or lattice do not require any particular sectional shape. The sectional shape of the inner spaces may be circular, elliptical, triangular and quadrangular.

The tape layer 150 is formed on one surface of the second insulating or dielectric film 130 opposite to the functional layer 140. The tape layer 150 includes an adhesive layer 151 and a release film 152 attached to one surface of the adhesive layer 151. The transmission wire 100 can easily be attached to a desired location by removing the release film 152 and bringing the adhesive layer 151 into contact with the desired location. The release film may be transparent or opaque. Any release film known in the art can be used without limitation. Preferably, the release film 152 may be one coated with a silicone resin or a fluorine resin.

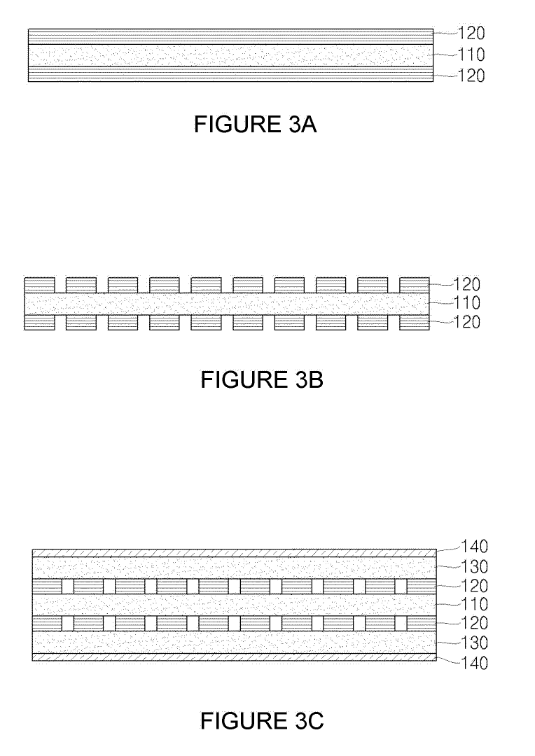

FIG. 2 is a flow chart illustrating a method for fabricating a flat transmission wire according to a first embodiment of the present invention. As illustrated in FIG. 2, the method includes the following steps: formation of a transmission layer (S11); patterning (S12); and formation of a functional layer (S13). According to the method, the transmission layer is formed by adhering a conductive material to an insulating or dielectric film using a pressure-sensitive adhesive, not by metal deposition. The use of the pressure-sensitive adhesive makes it easy to convert the transmission layer in the subsequent step. As a result, various fine patterns of transmission lines can be formed. According to the method, the transmission wire can be fabricated in an easy and simple manner without the need for expensive deposition equipment. In addition, the method generates smaller amounts of waste materials than the conventional deposition-based method. Therefore, the method is environmentally friendly.

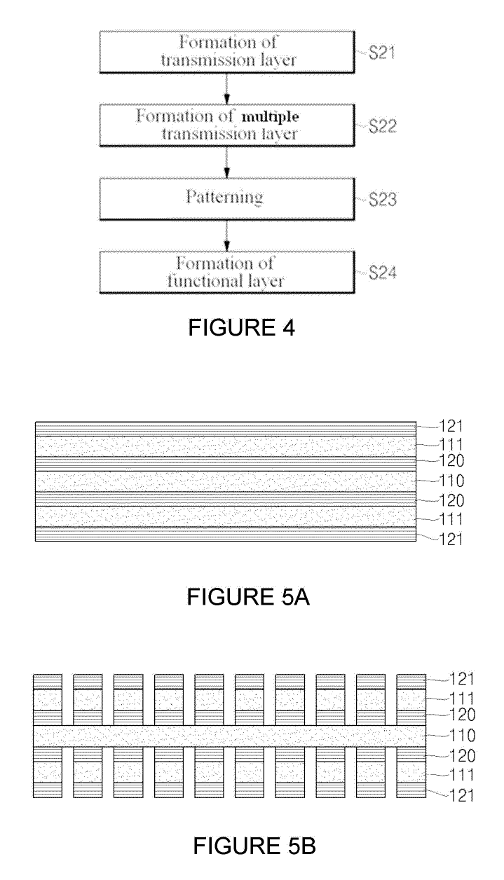

FIGS. 3A-3C are cross-sectional views sequentially illustrating the steps of the method.

As illustrated in FIG. 3A, in step S11, a conductive material is adhered to both surfaces of an insulating or dielectric film 110 using a pressure-sensitive adhesive to form transmission layers 120. The use of the pressure-sensitive adhesive makes it easy for the transmission layers 120 to be attached detachably to the insulating or dielectric film 110 in the subsequent converting step, thus enabling the formation of multiple transmission lines or fine patterns.

The conductive material is adhered to the insulating or dielectric films 110 through pressure-sensitive adhesive layers. The pressure-sensitive adhesive layers are formed by coating a pressure-sensitive adhesive on both surfaces of the insulating or dielectric film 110 and drying the pressure-sensitive adhesive at 50 to 250° C. for about 30 sec to about 1 hr. Each of the pressure-sensitive adhesive layers preferably has a thickness in the range of 1 to 40 μm. Outside this range, the conductive material may be insufficiently adhered to the insulating or dielectric films 110. The pressure-sensitive adhesive preferably has an adhesive strength of 0.1 to 200 gf/25 mm. If the adhesive strength of the pressure-sensitive adhesive is lower than 0.1 gf/25 mm, the adhesion of the conductive material to the insulating or dielectric films 110 is unsatisfactory. Meanwhile, if the adhesive strength of the pressure-sensitive adhesive is higher than 200 gf/25 mm, it may be difficult to detach the conductive material from the insulating or dielectric films 110, which makes it difficult to convert the transmission layers 120 in the subsequent step. Specific examples of the pressure-sensitive adhesive include acrylic resins, urethane resins, epoxy resins, urethane-acrylic resins, silicone resins, and amide resins. These resins may be used alone or as a mixture thereof. The pressure-sensitive adhesive may be coated by suitable processes known in the art. Specifically, the pressure-sensitive adhesive can be coated by gravure coating, microgravure coating, roll coating, offset coating, kiss bar coating, knife coating, Meyer bar coating, slot die coating or comma coating.

As illustrated in FIG. 3B, in step S12, the transmission layers 120 are converted to form transmission line patterns. This conversion enables the fabrication of the transmission wire including multiple transmission lines at uniform and fine intervals. In addition, various shapes of the transmission wire can be obtained.

Suitable converting processes include slitting, pressing and lamination. As a result of the conversion, two or more, preferably two to seventy linear transmission lines can be formed. Too many linear transmission lines are disadvantageous in terms of workability and cost. The linear transmission lines are spaced apart from each other at regular intervals and are parallel to the lengthwise direction thereof. The intervals between the linear transmission lines can be maintained constant along the lengthwise direction of the linear transmission lines. Each of the linear transmission lines may have a width of 1 to 200 nm. If the width is smaller than 1 mm, the workability and electrical properties of the transmission wire may be deteriorated. Meanwhile, if the width is larger than 200 mm, the material costs of the transmission wire increase. The linear transmission lines may be spaced apart from each other at intervals of 0.1 to 100 mm. If the intervals are shorter than 0.1 mm, the workability of the transmission wire may be deteriorated. Meanwhile, if the intervals are longer than 100 mm, the number of the transmission lines in the same area decreases, leading to deterioration in electrical properties.

As illustrated in FIG. 3C, in step S13, insulating or dielectric films 130, each of which has a functional layer 140 formed on one surface thereof, are adhered to the exposed surfaces of the patterned transmission layers 120. The functional layers 140 have at least one function selected from antistatic properties, electromagnetic shielding, electromagnetic absorption, dielectric properties, conductivity and colorability.

Each of the functional layers 140 can be formed by coating one surface of the insulating or dielectric film 130 with a conductive polymer, carbon black, an organic silver complex, a metal or a magnetic material. Alternatively, each of the functional layers 140 may be formed by forming a pattern on one surface of the insulating or dielectric film 130. The pattern may be formed by coating one surface of the insulating or dielectric film 130 with a coating solution containing a material selected from the group consisting of conductive polymers, carbon nanotubes, organic silver complexes, indium tin oxide and mixtures thereof. The pattern may be in the form of a mesh. The mesh pattern can be formed by suitable processes known in the art. Screen printing is preferred.

Each of the insulating or dielectric films 130 having the functional layer 140 is attached to one surface of the transmission layer 120 through an adhesive layer. The adhesive layer is formed by coating an adhesive to a thickness of 0.1 to 40 μm on the surface of the insulating or dielectric film 130 opposite to the functional layer 140 and drying the adhesive at 50 to 250° C. for about 30 sec to about 1 hr. Any coating method known in the art can be used without limitation. The adhesive may be a heat-curable adhesive having an adhesive strength of 0.2 to 200 gf/25 mm. The heat-curable adhesive is selected from the group consisting of acrylic resins, urethane resins, epoxy resins, urethane-acrylic resins, silicone resins, amide resins and mixtures thereof. The adhesive may also be a hot-melt adhesive. Any hot-melt adhesive known in the art can be used without limitation. Specifically, the hot-melt adhesive may contain a resin selected from the group consisting of ethylene vinyl acetate (EVA) resins, acrylic resins, polyamide resins, polyolefin resins, polyester resins and mixtures thereof. The conductive material is adhered to the hot-melt adhesive under heating at 50 to 150° C. The insulating or dielectric films 130 are the same as those described in the previous embodiment, and thus explanation thereof is omitted herein.

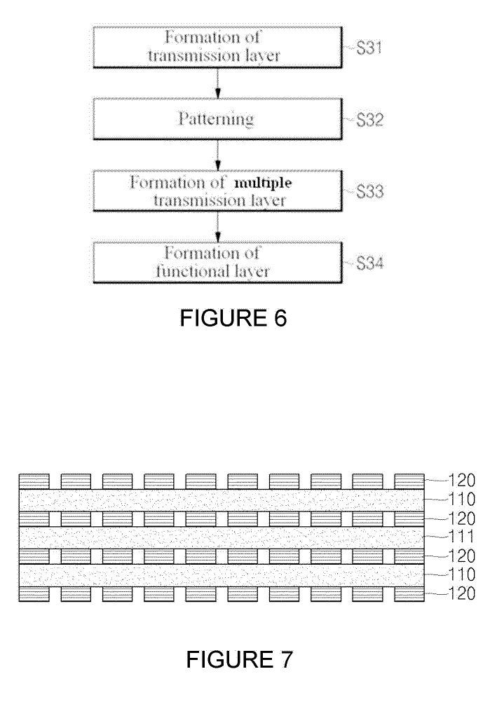

FIG. 4 is a flow chart illustrating a method for fabricating a flat transmission wire according to a second embodiment of the present invention. Referring to FIG. 4, the method includes the following steps: formation of a transmission layer (S21); formation of an additional transmission layer (S22); patterning (S23); and formation of a functional layer (S24). According to the method, the plurality of transmission layers formed before the patterning step are converted simultaneously in the patterning step. Therefore, the flat transmission wire having the transmission layers can be fabricated more uniformly and easily. Steps S21 and S24 are the same as steps S11 and S13 of the method according to the first embodiment, respectively, and thus explanation thereof is omitted herein. Steps S22 and S23 will be mainly explained below.

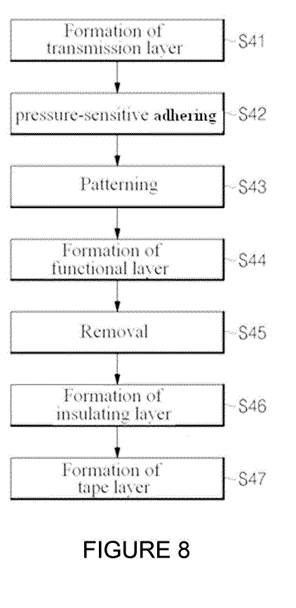

FIGS. 5A and 5B are cross-sectional views illustrating steps S22 and S23.

As illustrated in FIG. 5A, in step S22, an insulating or dielectric film 111 is adhered to one surface of each of the transmission layers 120. A conductive material is adhered to one surface of the insulating or dielectric film 111. This procedure may be repeated to increase the number of the transmission layers 120 and 121 in the flat transmission wire as required.

As illustrated in FIG. 5B, in step S23, the transmission layers 120 and 121 formed in steps S21 and S22 are converted to form transmission line patterns. All insulating or dielectric films and transmission layers other than the central insulating or dielectric film formed in step S21 are converted. Step S23 is carried out in the same manner as the patterning step S12 of the method according to the first embodiment.

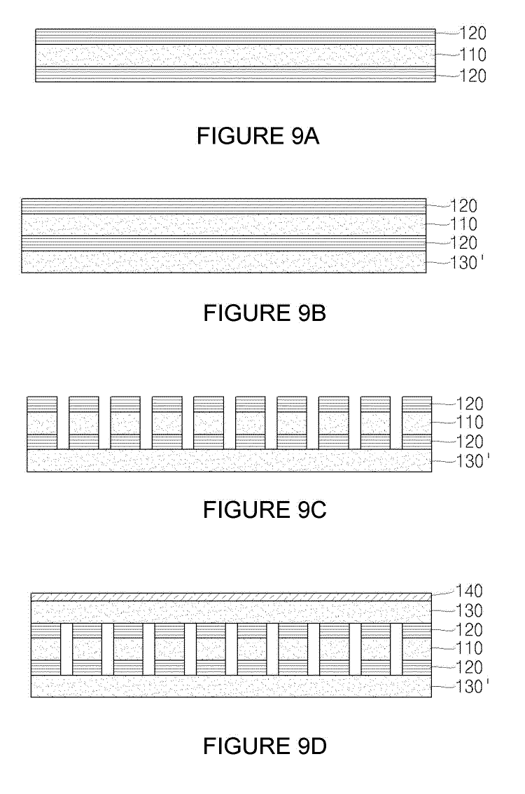

FIG. 6 is a flow chart illustrating a method for fabricating a flat transmission wire according to third embodiment of the present invention. Referring to FIG. 6, the method may include the following steps: formation of a transmission layer (S31); patterning (S32); formation of an additional transmission layer (S33); and formation of a functional layer (S34). Steps S31, S32 and S34 are the same as steps S11, S12 and S13 of the method according to the first embodiment, respectively, and thus explanation thereof is omitted herein. Step S33 will be mainly explained below.

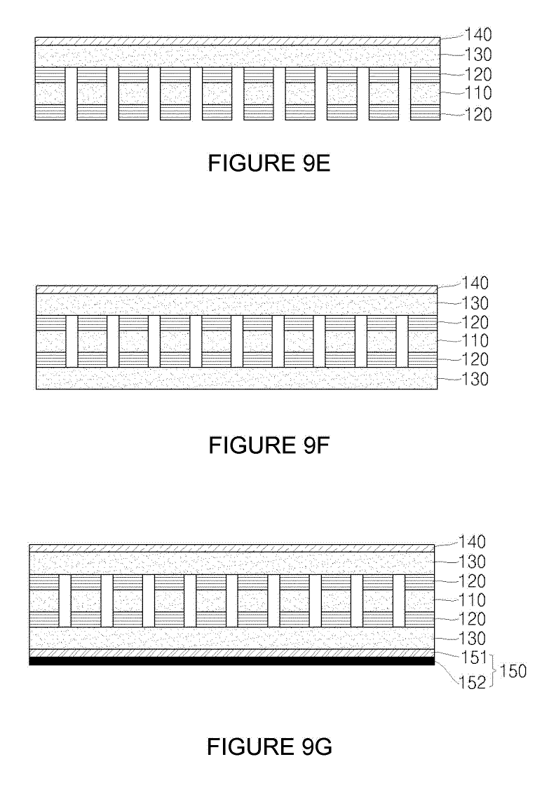

FIG. 7 is a cross-sectional view illustrating step S33. As illustrated in FIG. 7, in step S33, the flat transmission wire fabricated through steps S31 and S32 is adhered to each of both surfaces of an insulating or dielectric film 111. If needed, this procedure may be repeated to increase the number of the transmission layers in the final flat uniform transmission wire.

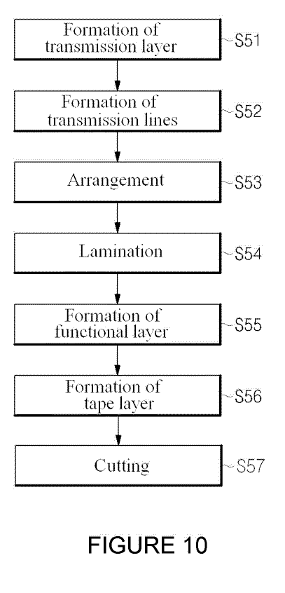

FIG. 8 is a flow chart illustrating a method for fabricating a flat transmission wire according to fourth embodiment of the present invention. Referring to FIG. 8, the method may include the following steps: formation of a transmission layer (S41); adhesion using a pressure-sensitive adhesive (S42); patterning (S43); formation of a functional layer (S44); removal (S45); formation of an insulating layer (S46); and formation of a tape layer (S47). According to the method, the converting step is easy to carry out to make the transmission wire fine and uniform, and the respective layers of the transmission wire are adhered to each other with improved binding strength to prevent them from being detached during subsequent handling. Step S44 is the same as step S13 of the method according to the first embodiment, and thus explanation thereof is omitted herein.

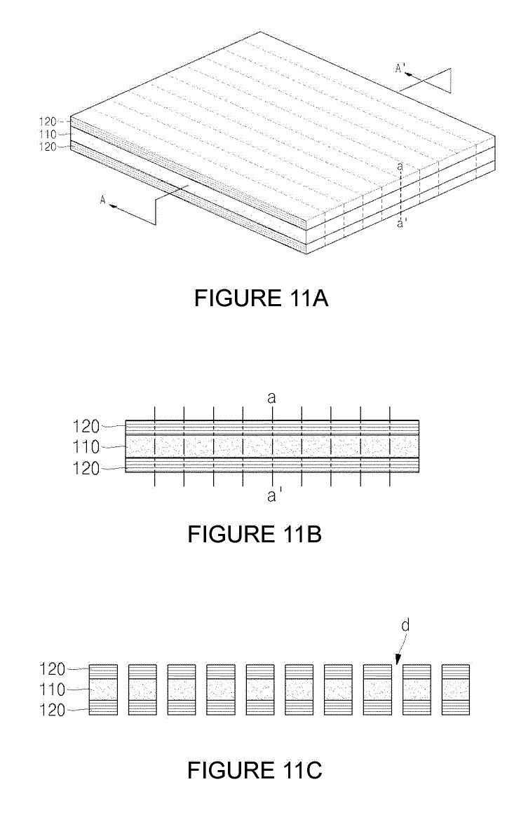

FIGS. 9A-9G are cross-sectional views sequentially illustrating the steps of the method of FIG. 8.

As illustrated in FIG. 9A, in step S41, a conductive material is adhered to both surfaces of an insulating or dielectric film 110 to form transmission layers 120. The binding strength between the conductive material and the insulating or dielectric film 110 is improved using an adhesive rather than using a pressure-sensitive adhesive. The improved binding strength prevents transmission lines from being detached during the fabrication steps and subsequent handling. The conductive material is adhered to both surfaces of the insulating or dielectric film 110 through adhesive layers. Each of the adhesive layers is formed by coating an adhesive to a thickness of 0.1 to 40 μm on one surface of the insulating or dielectric film 110 and drying the adhesive at 50 to 250° C. for about 30 sec to about 1 hr. Any coating method known in the art can be used without limitation. For example, the coating may be performed by gravure coating, microgravure coating, roll coating, offset coating, kiss bar coating, knife coating, Meyer bar coating, slot die coating or comma coating. The adhesive may be a heat-curable adhesive having an adhesive strength of 300 to 2,000 gf/25 mm. The heat-curable adhesive is selected from the group consisting of acrylic resins, urethane resins, epoxy resins, urethane-acrylic resins, silicone resins and amide resins. The adhesive may also be a hot-melt adhesive. Any hot-melt adhesive known in the art can be used without limitation. Specifically, the hot-melt adhesive may contain a resin selected from the group consisting of ethylene vinyl acetate (EVA) resins, acrylic resins, polyamide resins, polyolefin resins, polyester resins and mixtures thereof. The conductive material is adhered to the hot-melt adhesive under heating at 50 to 150° C. The conductive material and the insulating or dielectric film are the same as those described in the previous embodiments, and thus explanation thereof is omitted herein.

As illustrated in FIG. 9B, in step S42, an insulating or dielectric film 130′ is adhered to one surface of one of the transmission layers 120 using a pressure-sensitive adhesive. The adhesion of the insulating or dielectric film 130′ using the pressure-sensitive adhesive facilitates subsequent converting of the insulating or dielectric film 110 and the transmission layers 120. The insulating or dielectric film 130′ is removed after the converting step. The insulating or dielectric film 130′ is adhered to one surface of one of the transmission layers 120 through a releasable pressure-sensitive adhesive layer. The releasable pressure-sensitive adhesive layer is formed by applying a coating solution containing a material selected from the group consisting of acrylic resins, carbamate resins, polyolefin resins, chromium stearate, silicone resins, fluorine resins and mixtures thereof to one surface of the insulating or dielectric film 130′, followed by drying the coating solution at 50 to 200° C. for about 5 min to about 1 hr. Any coating method known in the art can be used without limitation. Specifically, the coating solution can be coated by gravure coating, microgravure coating, roll coating, offset coating, kiss bar coating, knife coating, Meyer bar coating, slot die coating or comma coating. The releasable pressure-sensitive adhesive layer preferably has an adhesive strength of 0.1 to 100 gf/25 mm. The releasable pressure-sensitive adhesive layer having an adhesive strength lower than 0.1 gf/25 mm is not attached to the insulating or dielectric film 130′. Meanwhile, it may be difficult to detach the releasable pressure-sensitive adhesive layer having an adhesive strength higher than 100 gf/25 mm from the insulating or dielectric film 130′.

As illustrated in FIG. 9C, in step S43, the insulating or dielectric film 110 and the transmission layers 120 are converted to form a transmission line pattern. The transmission layer 120 is easily detached from the insulating or dielectric film 130′ adhered to the releasable pressure-sensitive adhesive layer using the pressure-sensitive adhesive layer in step S42, so that the insulating or dielectric film 110 and the transmission layers 120 can be easily converted and uniform multiple transmission lines can be formed.

As illustrated in FIG. 9E, in step S45, the insulating or dielectric film 130′ is removed. The releasable pressure-sensitive adhesive layer makes the insulating or dielectric film 130′ easy to remove. The insulating or dielectric film 130′ is removed to expose the patterned transmission layers 120.

As illustrated in FIG. 9F, in step S46, an insulating or dielectric film 130 is adhered to one surface of one of the patterned transmission layers 120. The insulating or dielectric film 130 serves to cover the transmission layer 120 adhered thereto.

As illustrated in FIG. 9G, in step S47, an adhesive layer 151 is formed on one surface of the insulating or dielectric film 130, and a release film 152 is attached to one surface of the adhesive layer 151. The adhesive layer 151 is formed by applying a coating solution containing a resin selected from the group consisting of acrylic resins, urethane resins, epoxy resins, urethane-acrylic resins, silicone resins, amide resins and mixtures thereof to one surface of the insulating or dielectric film 130, followed by drying the coating solution at 50 to 200° C. for about 5 min to about 1 hr. Any coating method known in the art can be used without limitation, and specific examples include gravure coating, microgravure coating, roll coating, offset coating, kiss bar coating, knife coating, Meyer bar coating, slot die coating and comma coating.

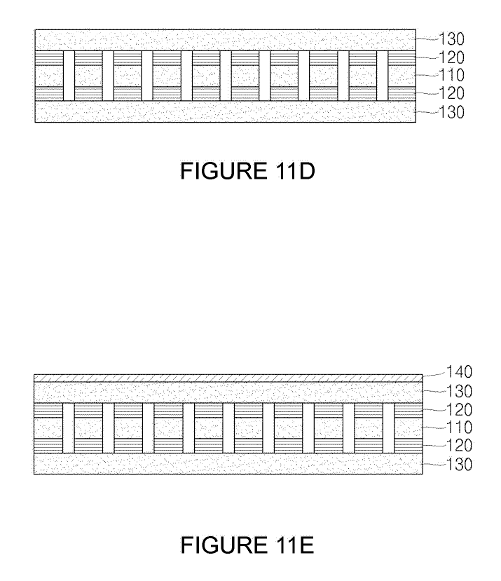

FIG. 10 is a flow chart illustrating a method for fabricating a flat transmission wire according to a fifth embodiment of the present invention. Referring to FIG. 10, the method may include the following steps: formation of a transmission layer (S51); formation of transmission lines (S52); arrangement (S53); lamination (S54); formation of a functional layer (S55); formation of a tape layer 150 (S56); and cutting (S57).

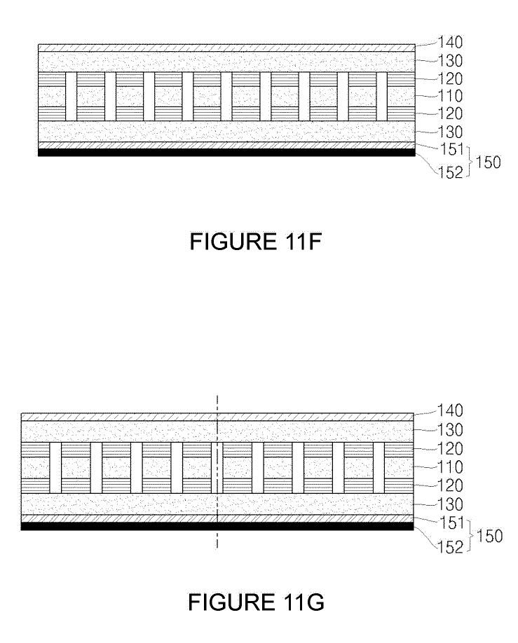

Steps S54, S55 and S56 are not necessarily carried out in this order. For example, steps S55 and S56 may be carried out before step S54. According to the method, the flat transmission wire can be fabricated in a simple and easy manner. Further, the flat transmission wire can be cut into smaller flat transmission wires through a series of consecutive steps, contributing to the improvement of efficiency and the reduction of working time. Further, step S53 enables the formation of a plurality of transmission lines arranged at uniform and fine intervals. FIG. 11A is a perspective view illustrating step S51, and FIGS. 11B-11G are cross-sectional views sequentially illustrating the other steps of the method.

Specifically, FIG. 11B is a cross-sectional view taken along line A-A′ of FIG. 11A and illustrates step S52. As illustrated in FIG. 11B, in step S52, an insulating or dielectric film 110 and transmission layers 120 formed in step S51 are cut in a direction perpendicular to the upper surface of the flat transmission wire and parallel to the lengthwise direction of the flat transmission wire to form two or more transmission lines. Referring to FIG. 11B, the insulating or dielectric film 110 and the transmission layers 120 are cut in the a-a′ direction. Assuming that the flat linear transmission wire has a square upper surface, the lengthwise direction may be a horizontal or vertical direction with respect to the upper surface of the flat linear transmission wire. Assuming that the flat linear transmission wire has a rectangular upper surface having two shorter sides and two longer sides, the lengthwise direction may be a direction along the longer sides. Any cutting method known in the art may be used without limitation. Slitting is preferred. Each of the transmission lines may have a uniform width in the range of 1 to 200 nm. If the transmission lines are narrower than 1 mm, the workability and the electrical properties of the transmission wire may be deteriorated. Meanwhile, if the linear transmission lines are wider than 200 mm, the material costs of the transmission wire increase.

As illustrated in FIG. 11C, in step S53, the transmission lines are spaced apart from each other at regular intervals (d). The method allows the transmission lines to be arranged at more fine intervals than conventional methods in which transmission lines are formed by deposition or are attached individually to an insulating film. The transmission lines may be arranged at regular intervals by suitable methods known in the art. Preferably, the transmission lines are passed between pitch rollers to maintain the intervals between the transmission lines constant. The intervals (d) may be from 0.1 to 100 mm. If the intervals are shorter than 0.1 mm, the workability of the transmission wire may be deteriorated. Meanwhile, if the intervals between the transmission lines are longer than 100 mm, the number of the transmission lines per unit area is reduced, leading to poor electrical properties of the transmission wire.

As illustrated in FIG. 11D, in step S54, insulating or dielectric films 130 are laminated on both surfaces of each of the transmission lines spaced apart from each other at regular intervals. An adhesive layer is interposed between one of the insulating or dielectric films 130 and one surface of each of the transmission lines. The adhesive layer is formed by applying a coating solution containing an acrylic resin, a urethane resin, an epoxy resin, a urethane-acrylic resin, a silicone resin or an amide resin as a heat-curable adhesive or an ethylene vinyl acetate (EVA) resin, an acrylic resin, a polyamide resin, a polyolefin resin or a polyester resin as a hot-melt adhesive to one surface of each of the insulating or dielectric films 130. Specifically, the transmission lines are adhered to the insulating or dielectric films 130 by thermally curing the adhesive layers at 30 to 350° C. for about 30 sec to about 1 hr or melting the adhesive layers at 50 to 150° C.

As illustrated in FIG. 11G, in step S57, the flat transmission wire including the plurality (n≧2) of the transmission lines formed in steps S51 through S54 is cut between the adjacent transmission lines in a direction perpendicular to the upper surface of the flat transmission wire and parallel to the lengthwise direction of the flat transmission wire to fabricate smaller flat transmission wires, each including one or more (n) transmission lines fewer than n. That is, the single flat transmission wire including the plurality (n) of transmission wires is cut to fabricate two or more smaller flat transmission wires including a desired number (for example, m) of the transmission lines. The steps for the fabrication of the flat transmission wire including the plurality (n) of transmission wires and step S57 are carried out consecutively to fabricate two or more smaller flat transmission wires, each including a desired number (m) of the transmission lines. Any cutting method known in the art can be used without limitation.

Hereinafter, the present invention will be explained with reference to the following examples, including comparative examples. These examples are given for the purpose of illustration and are not intended to limit the present invention.

### EXAMPLES

### Example 1

1-1. A heat-curable acrylic pressure-sensitive adhesive having an adhesive strength of 60 gf/25 mm was coated to a thickness of 20 μm on both surfaces of a polyethylene film (thickness=0.05 mm, width=50 mm) by gravure coating, and dried at 100° C. for 10 min to form pressure-sensitive adhesive layers.

1-2. Copper was adhered to both surfaces of the polyethylene film through the pressure-sensitive adhesive layers to form transmission layers.

1-3. Each of the transmission layers was slit to form four linear transmission lines. The transmission lines had a width of 5 mm and were spaced apart from each other at intervals of 5 mm.

1-4. An acrylic adhesive having an adhesive strength of 60 gf/25 mm was coated to a thickness of 20 μm on one surface of a polyethylene film (thickness=0.05 mm, width=20 mm) by gravure coating, and dried at 100° C. for 30 min to form an adhesive layer. The polyethylene film was adhered to one of the transmission layers including the transmission lines through the adhesive layer to fabricate a flat transmission wire.

### Example 2

2-1. An acrylic adhesive having an adhesive strength of 1,000 gf/25 mm was coated to a thickness of 20 μm on both surfaces of an insulating film (thickness=0.05 mm, width=50 mm) by gravure coating, and dried at 100° C. for 30 min to form adhesive layers.

2-2. Two transmission layers having transmission lines, which were produced in the same manner as in 1-1 through 1-3, were adhered to both surfaces of the insulating film through the adhesive layers.

2-3. A polyethylene film having an adhesive layer formed on one surface thereof, which was produced in the same manner as in 1-4, was adhered to one surface of each of the transmission layers to fabricate a flat transmission wire.

### Example 3

3-1. A heat-curable acrylic adhesive having an adhesive strength of 1,000 gf/25 mm was coated to a thickness of 20 μm on both surfaces of a polyethylene film (thickness=0.05 mm, width=50 mm) by gravure coating, and dried at 100° C. for 10 min to form adhesive layers. Copper was adhered to one surface of the polyethylene film through one of the adhesive layers to form a transmission layer.

3-2. The polyethylene film having the transmission layer formed on one surface thereof was adhered to one surface of one of two transmission layers of a polyethylene film, which was produced in the same manner as in 1-1 and 1-2.

3-3. The polypropylene film and the transmission layers were converted in the same manner as in 1-3 to form five transmission lines.

3-4. A polyethylene film was adhered to one surface of each of the transmission layers including the transmission lines to fabricate a flat transmission wire.

### Example 4

4-1. A hot-melt adhesive was coated to a thickness of 20 μm on both surfaces of a 0.08 mm thick polypropylene film to form adhesive layers. 14 μm thick aluminum foils were laminated on both surfaces of the polypropylene film through the adhesive layers under heating to form transmission layers.

4-2. A heat-curable releasable acrylic pressure-sensitive adhesive having an adhesive strength of 60 gf/25 mm was coated to a thickness of 20 μm on one surface of a polyethylene film by gravure coating, and dried at 100° C. for 10 min to form a releasable pressure-sensitive adhesive layer. The polyethylene film having the releasable pressure-sensitive adhesive layer was adhered to one surface of one of the transmission layers.

4-3. The polypropylene film, the transmission layers and the polyethylene film were converted to form transmission layers, each having five linear transmission lines. The transmission lines had a width of 4.5 mm and were spaced apart from each other at intervals of 0.8 mm.

4-4. 25 g of poly(3,4-ethylenedioxythiophene) (PEDOT) as a conductive polymer, 15 g of a water-soluble acrylic resin, 25 g of water and 35 g of isopropyl alcohol were mixed together to prepare a conductive coating solution. The coating solution was coated on one surface of a 0.08 mm thick polypropylene film by screen printing to form a functional layer in the form of a mesh (length=1 cm, width=1 cm). A hot-melt adhesive was coated to a thickness of 20 μm on the other surface of the polypropylene film to form an adhesive layer.

4-5. The polypropylene film including the functional layer and the adhesive layer was adhered to one surface of one of the transmission layers including the transmission lines. The polyethylene film including the releasable pressure-sensitive adhesive layer was removed.

4-6. A polypropylene film was laminated on one surface of the transmission layer, from which the polyethylene film including the releasable pressure-sensitive adhesive layer had been removed, using a hot-melt adhesive by heating to 80-100° C. to fabricate a flat transmission wire.

### Example 5

An acrylic adhesive having an adhesive strength of 1,000 gf/25 mm was coated to a thickness of 20 μm on one surface of the outermost polypropylene film of the flat transmission wire fabricated in Example 4 by gravure coating to form an adhesive layer. A release film was adhered to the adhesive layer to fabricate a flat transmission wire.

### Example 6

A flat transmission wire was fabricated in the same manner as in Example 4, except that a conductive coating solution composed of 5 g of multi-walled carbon nanotubes (Hanwha Nanotec, Korea), 15 g of a water-soluble acrylic resin, 25 g of water and 55 g of isopropyl alcohol was coated on the upper surface of a 0.08 mm thick polypropylene film by screen printing to form a functional layer in the form of a mesh (length=1 cm, width=1 cm) in 4-4.

### Example 7

A flat transmission wire was fabricated in the same manner as in Example 4, except that a conductive coating solution composed of 15 g of an organic silver complex, 15 g of a water-soluble acrylic resin, 25 g of water and 45 g of isopropyl alcohol was coated on the upper surface of a 0.08 mm thick polypropylene film by screen printing to form a functional layer in the form of a mesh (length=1 cm, width=1 cm) in 4-4.

### Example 8

A flat transmission wire was fabricated in the same manner as in Example 4, except that ITO was coated on one surface of a polypropylene film instead of the conductive polymer in 4-4.

### Example 9

A flat transmission wire was fabricated in the same manner as in Example 4, except that a conductive coating solution composed of 5 g of single-walled carbon nanotubes (Hanwha Nanotec, Korea), 4 g of a printable coating composition (JR, Jin Kwang Chemical Co., Ltd., Korea), 1 g of silica, 15 g of a water-soluble acrylic resin, 25 g of water and 50 g of isopropyl alcohol was coated on a 0.08 mm thick polypropylene film by screen printing to form a functional layer in the form of a mesh (length=1 cm, width=1 cm) in 4-4.

### Example 10

10-1. A hot-melt adhesive was coated to a thickness of 20 μm on both surfaces of a 0.019 mm thick polyethylene terephthalate (PET) film to form adhesive layers. 7 μm thick aluminum foils were laminated on both surfaces of the PET film through the adhesive layers to form transmission layers.

10-2. Each of the transmission layers was slit in a direction perpendicular to the upper surface thereof and parallel to the lengthwise direction thereof to form five transmission lines, each having a width of 4.3 mm.

10-3. 25 g of poly(3,4-ethylenedioxythiophene) (PEDOT), 15 g of a water-soluble acrylic resin, 25 g of water and 35 g of isopropyl alcohol were mixed together to prepare a conductive coating solution. The coating solution was coated on one surface of a 0.05 mm thick PET film by screen printing to form a functional layer in the form of a mesh (1 cm×1 cm). A hot-melt adhesive was coated to a thickness of 20 μm on the other surface of the PET film to form an adhesive layer.

10-4. The five transmission lines were passed between pitch rollers so that the interval between the adjacent transmission lines was adjusted to 0.8 mm. The PET film having the adhesive layer on one surface thereof and the functional layer having on the other surface thereof was laminated on the transmission lines of one of the transmission layers in a thermal laminator to fabricate a flat transmission wire including transmission lines spaced apart from each other at uniform intervals.

### Example 11

A flat transmission wire was fabricated in the same manner as in Example 10, except that fifteen transmission lines produced in 10-4 were passed between pitch rollers. Subsequently, the flat linear transmission wire including the fifteen transmission lines was cut into three smaller transmission wires, each of which included five transmission lines.

### Example 12

12-1. A hot-melt adhesive was coated to a thickness of 20 μm on both surfaces of a 0.019 mm thick PET film to form adhesive layers. 7 μm thick aluminum foils were laminated on both surfaces of the PET film through the adhesive layers to form transmission layers.

12-2. The PET film, the adhesive layers and the transmission layers were slit to form five transmission lines, each having a width of 4.3 mm.

12-3. 25 g of PEDOT, 15 g of a water-soluble acrylic resin, 25 g of water and 35 g of isopropyl alcohol were mixed together to prepare a conductive coating solution. The coating solution was coated on one surface of a 0.05 mm thick PET film by screen printing to form a functional layer in the form of a mesh (1 cm×1 cm). A hot-melt adhesive was coated to a thickness of 20 μm on the other surface of the PET to form an adhesive layer.

12-4. The five transmission lines were passed between pitch rollers so that the interval between the adjacent transmission lines was adjusted to 0.8 mm. The PET film having the functional layer was laminated on the transmission lines of one of the transmission layers in a thermal laminator. Another PET film having no functional layer was laminated on the transmission lines of the other transmission layer.

12-5. An acrylic adhesive having an adhesive strength of 1,000 gf/25 mm was coated to a thickness of 20 μm on the laminated PET film having no patterned functional layer by gravure coating to form an adhesive layer, and a release film was attached to the adhesive layer to form a tape layer, completing the fabrication of a flat transmission wire.

### Example 13

A flat transmission wire was fabricated in the same manner as in Example 10, except that a conductive coating solution containing 5 g of multi-walled carbon nanotubes (Hanwha Nanotec, Korea), 15 g of a water-soluble acrylic resin, 25 g of water and 55 g of isopropyl alcohol was used in 10-3.

### Example 14

A flat transmission wire was fabricated in the same manner as in Example 10, except that a conductive coating solution containing 15 g of an organic silver complex, 15 g of a water-soluble acrylic resin, 25 g of water and 45 g of isopropyl alcohol was used in 10-3.

### Example 15

A flat transmission wire was fabricated in the same manner as in Example 10, except that ITO was used instead of poly(3,4-ethylenedioxythiophene) in 10-3.

### Example 16

A flat transmission wire was fabricated in the same manner as in Example 10, except that a conductive coating solution containing 5 g of single-walled carbon nanotubes (Hanwha Nanotec, Korea), 4 g of a printable coating composition (JR, Jin Kwang Chemical Co., Ltd., Korea), 1 g of silica, 15 g of a water-soluble acrylic resin, 25 g of water and 50 g of isopropyl alcohol was used in 10-3.

### Example 17

A flat transmission wire was fabricated in the same manner as in Example 10, except that a conductive coating solution containing 4 g of poly(3,4-ethylenedioxythiophene), 1 g of single-walled carbon nanotubes (Hanwha Nanotec, Korea), 4 g of a printable coating composition (JR, Jin Kwang Chemical Co., Ltd., Korea), 1 g of silica, 15 g of a water-soluble acrylic resin, 25 g of water and 50 g of isopropyl alcohol was used in 10-3.

### Example 18

18-1. A hot-melt adhesive was coated to a thickness of 20 μm on both surfaces of a 0.019 mm thick PET film to form adhesive layers. 7 μm thick aluminum foils were laminated on both surfaces of the PET film through the adhesive layers to form transmission layers.

18-2. The PET film, the adhesive layers and the transmission layers were slit in a direction perpendicular to the upper surfaces of the transmission layers and parallel to the lengthwise directions of the transmission layers to form five transmission lines, each having a width of 4.3 mm.

18-3. A hot-melt adhesive was coated to a thickness of 0.05 mm on one surface of a PET film to form an adhesive layer.

18-4. The five transmission lines were passed between pitch rollers so that the interval between the adjacent transmission lines was adjusted to 0.8 mm. The PET film having the adhesive layer formed on one surface thereof was laminated on one surface of each of the transmission lines in a thermal laminator to fabricate a flat transmission wire.

### Example 19

A flat transmission wire was fabricated in the same manner as in Example 10, except that the conductive polymer coating solution was coated over the entire surface of a PET film without patterning instead of screen printing in the form of a mesh in 10-3.

### Example 20

A flat transmission wire was fabricated in the same manner as in Example 10, except that polypropylene films were used instead of the PET films.

As is apparent from the above description, the flat transmission wire of the present invention is simple to install and has good appearance when exposed to the outside.

Further, the use of the flat transmission wire according to the present invention can contribute to the simplification of interconnection configuration, which gradually becomes more complex, and is advantageous in terms of interior decoration due to its colorability.

Further, the flat transmission wire of the present invention has controllable antistatic properties, electromagnetic shielding, electromagnetic absorption, dielectric properties, conductivity and impedance, and can minimize crosstalk and loss of transmission signal.

Further, the flat transmission wire of the present invention has a light unit weight, can be cut to a desired size, and can be directly attached to a desired location. That is, the flat transmission wire of the present invention has excellent workability.

Further, the flat transmission wire of the present invention can be connected to connectors of a variety of electric/electronic devices, including audio equipment, video equipment, cable televisions, antennas, local area networks (LANs), telephones and multimedia. That is, the flat transmission wire of the present invention is simple to use.

Further, the methods of the present invention enable the fabrication of transmission wires including a plurality of uniform and fine transmission lines because of the intervals between the adjacent transmission lines are freely controllable. According to the methods of the present invention, transmission wires of various shapes and kinds can be fabricated. Further, two or more flat transmission wires can be fabricated through a series of consecutive steps, contributing to the improvement of workability and the reduction of working time.

Further, the methods of the present invention have advantages in that flat transmission wires can be fabricated in a simple and easy manner at low cost without the need for complex equipment, compared to the conventional deposition-based method.

Further, the methods of the present invention can contribute to resource saving because there is no need to use heat during processing and generate smaller amounts of waste materials and carbon than the conventional deposition-based method. Therefore, the methods of the present invention are environmentally friendly.

What is claimed is:

1. A flat transmission wire comprising:
a first insulating or dielectric film,
a transmission layer formed on at least one surface of the first insulating or dielectric film so as to transmit electrical signals therethrough,
a second insulating or dielectric film formed on one surface of the transmission layer, and
a functional layer formed on one surface of the second insulating or dielectric film.

2. The flat transmission wire of claim 1, wherein the transmission layer comprises a plurality of linear transmission lines.

3. The flat transmission wire of claim 1, wherein the functional layer has at least one function selected from the group consisting of antistatic properties, electromagnetic shielding, electromagnetic absorption, dielectric properties, conductivity and colorability.

4. The flat transmission wire of claim 1, wherein the functional layer contains a material selected from the group consisting of conductive polymers, carbon nanotubes (CNTs), organic silver complexes, indium tin oxide (ITO), and mixtures thereof.

5. The flat transmission wire of claim 4, wherein the conductive polymers comprise polyaniline, polypyrrole, polythiophene, poly(3,4-ethylenethiophene), derivatives thereof, copolymers thereof, π-conjugated conductive polymers soluble in water, π-conjugated conductive polymers soluble in organic solvents, and mixtures thereof.

6. The flat transmission wire of claim 4, wherein the organic silver complexes comprise a reaction product of a silver-containing compound and an ammonium compound of Formula 1: 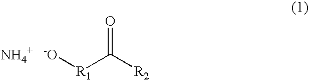
wherein R₁ is C₁-C₅ alkyl, and R₂ is hydrogen, hydroxyl, C₁-C₅ alkoxy, C₁-C₅ alkylammonium, C₁-C₆ alkoxyammonium or a substituted or unsubstituted primary, secondary or tertiary amine.

7. The flat transmission wire of claim 1, wherein the functional layer is formed in a mesh pattern.

8. The flat transmission wire of claim 1, further comprising:
another second insulating or dielectric film formed on a surface of the transmission later opposite to surface where the functional layer is formed;
a tape layer formed on one surface of the another second insulating or dielectric film opposite to the functional layer and that comprises an adhesive layer; and
a release film attached to one surface of the adhesive layer.

9. A method for fabricating a flat transmission wire, the method comprising the steps of:
forming a transmission layer by pressure-sensitive adhering a conductive material to at least one surface of an insulating or dielectric film; and
performing a patterning process by converting the transmission layer in order to form a transmission line pattern.

10. The method of claim 9, further comprising forming multiple transmission layers by adhering a flat transmission wire to each of both surfaces of an insulating or dielectric film.

11. The method of claim 9, further comprising the step of forming multiple transmission layer by adhering an insulating or dielectric film having a conductive material adhered to one surface thereof to one surface of the transmission layer.

12. The method of claim 9, wherein the converting is performed by slitting, pressing or lamination.

13. The method of claim 9, wherein the conductive material is adhered by a pressure-sensitive adhesive which has an adhesive strength of 0.2 to 200 gf/25 mm and is selected from the group consisting of acrylic resins, urethane resins, epoxy resins, urethane-acrylic resins, silicone resins, amide resins and mixtures thereof.

14. The method of claim 9, further comprising the step of forming a functional layer after performing the patterning process by adhering an additional insulating or dielectric film having a functional layer formed on one surface thereof to one surface of the transmission layer, wherein the functional layer has at least one function selected from antistatic properties, electromagnetic shielding, electromagnetic absorption, dielectric properties, conductivity and colorability.

15. A method for fabricating a flat transmission wire, the method comprising the steps of:
forming a transmission layer by adhering a conductive material to one surface of a first insulating or dielectric film;
pressure-sensitive adhering a second insulating or dielectric film to one surface of the transmission layer;
performing a patterning process by converting the first insulating or dielectric film to the transmission layer to form a transmission line pattern;
forming a functional layer by adhering a third insulating or dielectric film having a functional layer formed on one surface thereof to one surface of the patterned transmission layer; and
removing the second insulating or dielectric film.

16. The method of claim 15, wherein the functional layer is formed in a mesh pattern.

17. The method of claim 15, further comprising the step of forming a insulating layer by adhering a fourth insulating or dielectric film to the surface of the transmission layer from which the second insulating or dielectric film has been removed.

18. The method of claim 17, further comprising the step of forming a tape layer by coating an adhesive on one surface of the fourth insulating or dielectric film to form an adhesive layer and attaching a release film to one surface of the adhesive layer.

19. A method for fabricating a flat transmission wire, the method comprising the steps of:
forming a transmission layer by adhering a conductive material to at least one surface of a first insulating or dielectric film;
forming a transmission line by cutting the first insulating or dielectric film to the transmission layer in a direction perpendicular to the upper surface of the flat transmission wire and parallel to the lengthwise direction of the flat transmission wire to form a plurality of transmission lines;
arranging the transmission lines so as to be spaced apart from each other at regular intervals; and
laminating a second insulating or dielectric film on at least one surface of each of the transmission lines.

20. The method of claim 19, further comprising the step of forming a functional layer by coating a conductive coating solution on one surface of the second insulating or dielectric film.

21. The method of claim 20, wherein the functional layer is formed in a mesh pattern.

22. The method of claim 19, further comprising the step of cutting between two adjacent transmission lines of plurality (n) of transmission lines of the flat transmission wire in a direction perpendicular to the upper surface of the flat transmission wire and parallel to the lengthwise direction of the flat transmission wire to fabricate multiple flat transmission wires, each including one or more (m) transmission lines, wherein m is less than n.

23. The method of claim 19, wherein the lamination is performed by thermal curing or melting at a temperature of 30 to 250° C. to adhere the second insulating or dielectric film to the transmission lines.
